(19) United States
(12) Patent Application Publication
(10) Pub. No.: US 2024/0039552 A1
(43) Pub. Date: Feb. 1, 2024

(54) AD CONVERTER, SENSOR DEVICE, AND VOLTAGE MEASURING DEVICE

(71) Applicant: Rohm Co., Ltd., Kyoto (JP)

(72) Inventor: Takashi MIYAKE, Kyoto (JP)

(21) Appl. No.: 18/359,504

(22) Filed: Jul. 26, 2023

(30) Foreign Application Priority Data
Jul. 29, 2022 (JP) 2022-121329

(51) Int. Cl. H03M 1/34; G01R 19/25; G01L 9/00

(52) U.S. Cl. CPC H03M 1/34; G01R 19/25; G01L 9/0052

(57) ABSTRACT

An AD converter includes: an amplifier including first and second input ends; a capacitor connecting the first input end and an output end of the amplifier; a comparator including a first input end connected to the output end and a second input end; a first switch connected between an application end of the input voltage and the first input end; a second switch connected between a first node and application end of ground potential; and a controller performing ON/OFF control of the first and second switches, wherein the controller starts charging the capacitor by switching the first switch to ON state, thereafter discharge the capacitor by setting the second switch to ON state during offset regulation period to cancel increase in a charging amount of the capacitor, and measure discharging period from an end of the offset regulation period to switching of an output level of the comparator.

### CROSS-REFERENCE TO RELATED APPLICATION

This application is based upon and claims the benefit of priority from Japanese Patent Application No. 2022-121329, filed on Jul. 29, 2022, the entire contents of which are incorporated herein by reference.

### TECHNICAL FIELD

The present disclosure relates to an AD converter, and a sensor device and a voltage measuring device including the AD converter.

### BACKGROUND

In the related art, various sensors such as pressure sensors and temperature sensors are known. For example, in the related art, a pressure sensor including a resistance bridge circuit including piezoresistors is known.

### BRIEF DESCRIPTION OF DRAWINGS

The accompanying drawings, which are incorporated in and constitute a part of the specification, illustrate embodiments of the present disclosure.

FIG. 1 is a diagram showing a configuration of a sensor device according to a comparative example.

FIG. 2 is a timing chart showing an example of behaviors of an output voltage VINT and a comparator output CPout in the comparative example.

FIG. 3 is a diagram showing an example of an improved configuration of the comparative example.

FIG. 4 is a diagram showing a configuration of a sensor device according to a first embodiment of the present disclosure.

FIG. 5 is a timing chart showing an example of AD conversion operation in the first embodiment of the present disclosure (when ΔV>0).

FIG. 6 is a timing chart showing an example of AD conversion operation in the first embodiment of the present disclosure (when ΔV<0).

FIG. 7 is a flowchart of offset acquisition operation.

FIG. 8 is a timing chart showing an example of AD conversion operation in a second embodiment of the present disclosure (when ΔV>0).

FIG. 9 is a timing chart showing an example of AD conversion operation in the second embodiment of the present disclosure (when ΔV<0).

FIG. 10 is a diagram showing a configuration of a sensor device according to a third embodiment of the present disclosure.

FIG. 11 is a diagram showing a configuration of a voltage measuring device according to a fourth embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, exemplary embodiments of the present disclosure will be described with reference to the drawings.

### 1. Comparative Example

Here, prior to explanation of exemplary embodiments according to the present disclosure, a comparative example for comparison will be described. By explaining such a comparative example, problems become clearer.

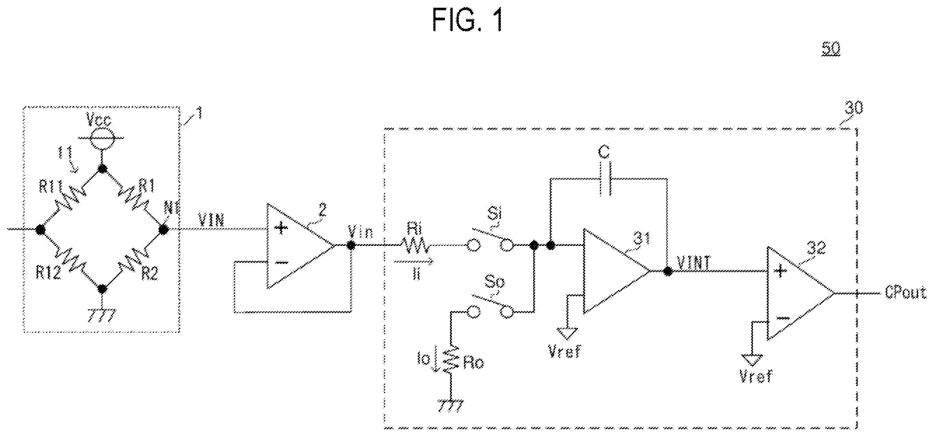

FIG. 1 is a diagram showing a configuration of a sensor device 50 according to the comparative example. The sensor device 50 shown in FIG. 1 includes a MEMS (Micro Electro Mechanical Systems) sensor 1, a voltage follower 2, and an AD converter 30.

The MEMS sensor 1 includes a resistance bridge circuit 11 including MEMS resistors R1, R2, R11, and R12. The MEMS resistors R1 and R2 are connected in series between an application end of a power supply voltage Vcc and an application end of a ground potential. The MEMS resistors R11 and R12 are connected in series between the application end of the power supply voltage Vcc and the application end of the ground potential.

The MEMS sensor 1 is configured by integrating a diaphragm and a resistance bridge circuit 11. For example, the resistance bridge circuit 11 is formed by using a Si substrate as the diaphragm and diffusing impurities into a surface of the Si substrate. The MEMS sensor 1 is a pressure sensor configured to use piezoresistive effect. The piezoresistive effect is a phenomenon that a resistance value changes when a pressure is applied to a resistor.

When a pressure is applied to the diaphragm, the resistance values of the MEMS resistors R1, R2, R11, and R12 change. Depending on the resistance values of the MEMS resistors R1 and R2, an input voltage VIN is generated at a node Ni to which R1 and R2 are connected.

The application of the resistance bridge circuit is not limited to pressure sensors, and may be, for example, temperature sensors.

The voltage follower 2 is configured to output an input voltage Vin based on the input voltage VIN.

The AD converter 30 is provided after the voltage follower 2. The AD converter 30 is configured as an integral type AD converter and includes an input resistor Ri, an input switch Si, an output resistor Ro, an output switch So, a capacitor C, an amplifier 31, and a comparator 32.

One end of the input resistor Ri is connected to an application end of the input voltage Vin. The other end of the input resistor Ri is connected to one end of the input switch Si. The other end of the input switch S1 is connected to a first input end of the amplifier 31. One end of the output switch So is connected to the first input end of the amplifier 31. The other end of the output switch So is connected to one end of the output resistor Ro. The other end of the output resistor Ro is connected to the application end of the ground potential. The capacitor C is connected between the first input end of the amplifier 31 and an output end of the amplifier 31. A second input end of the amplifier 31 is connected to an application end of a reference voltage Vref.

A first input end of the comparator 32 is connected to the output end of the amplifier 31. A second input end of the comparator 32 is connected to the application end of the reference voltage Vref.

Here, an operation of the AD converter 30 will be described. First, by turning on the input switch S1 and turning off the output switch So, an input current Ii flows through the input resistor Ri and the capacitor C is charged. At this time, assuming that Ti is a charging period and Vint is the voltage of the capacitor C, the following equation (1) is established.

Vint=(Ii×Ti)/C=Vref−VINT_{(T=Ti)} (1)

where VINT_{(T=Ti)} is the output voltage of the amplifier 31 after the charging period Ti has elapsed.

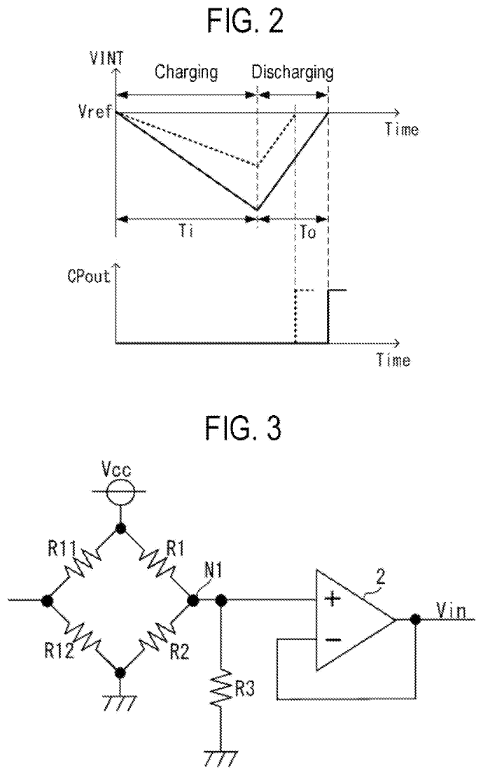

FIG. 2 is a timing chart showing an example of behaviors of the output voltage VINT and a comparator output CPout output from the comparator 32. As shown in FIG. 2, the output voltage VINT gradually decreases from the reference voltage Vref during the charging period Ti.

Next, by turning off the input switch S1 and turning on the output switch So, an output current Io flows through the output resistor Ro and the capacitor C is discharged. At this time, assuming that To is the discharging period required to discharge electric charges charged in the capacitor C during the charging period Ti, the following equation (2) is established.

To=(C×Vint)/Io (2)

Substituting the equation (1) into the equation (2),

To=(C×Vint)/Io=(Ii×Ti)/Io (3)

Here, Ii=(Vin−Vref)/Ri, and Io=Vref/Ro. In a case where Ri=Ro, the equation (3) becomes:

To/Ti=(Vin−Vref)/Vref (4)

As shown in FIG. 2, the output voltage VINT gradually rises during a discharging period To and reaches the reference voltage Vref when the discharging period To elapses. Since the comparator 32 is configured to compare the output voltage VINT with the reference voltage Vref, the comparator output CPout switches from a low level to a high level when the discharging period To elapses.

From the equation (4), in a case where the charging period Ti is a fixed value, the discharging period To changes according to the input voltage Vin. Therefore, the input voltage VIN may be detected by counting the discharging period To which is a time from a timing when the charging period Ti has elapsed to a timing when the level of the comparator output CPout is switched. Further, the output voltage VINT of a broken line shown in FIG. 2 indicates a case where the input voltage Vin is smaller than that in a case of the output voltage VINT of a solid line, and the discharging period To is shorter than that in the case of the output voltage VINT of the solid line.

However, in the above-described comparative example, an offset may occur in the input voltage Vin. Such an offset occurs, for example, when an offset occurs in the resistance values of the MEMS resistors R1 and R2 in the resistor bridge circuit 11. Assuming that ΔV is the offset of the input voltage Vin, from the above-described equation (4),

To/Ti=((Vin+ΔV)−Vref)/Vref (5),

and an error occurs in To (that is, an AD conversion output of the AD converter 30). AV may take a positive value or a negative value.

Therefore, in order to suppress the offset of the input voltage Vin, for example, a configuration as shown in FIG. 3 may be considered. In the configuration shown in FIG. 3, a correction resistor R3 is connected between a node Ni to which the MEMS resistors R1 and R2 are connected and the application end of the ground potential.

Here, ideally, R1=R2, but R1 is assumed to be smaller by 10% due to the offset. In this case, a combined resistance (lower combined resistance) R2′ of the resistors R2 and R3 is

R2′=(R2×R3)/(R2+R3)=(R1×R3)/(R1+R3)=0.9R1 (6)

From the above-described equation (6), since R3=9R1, it is sufficient to add R3 having a resistance value nine times as large as that of R1.

However, R1 and R2′ may not be in one-to-one relationship due to R3. It is often difficult to form R3 with the same resistance as R1 and R2. For example, in a case where R1 and R2 increase by 10% due to temperature characteristics and R3 changes by 0%, R2′ increases by 9%. Therefore, adding a resistor like R3 presents a challenge.

### 2. First Embodiment

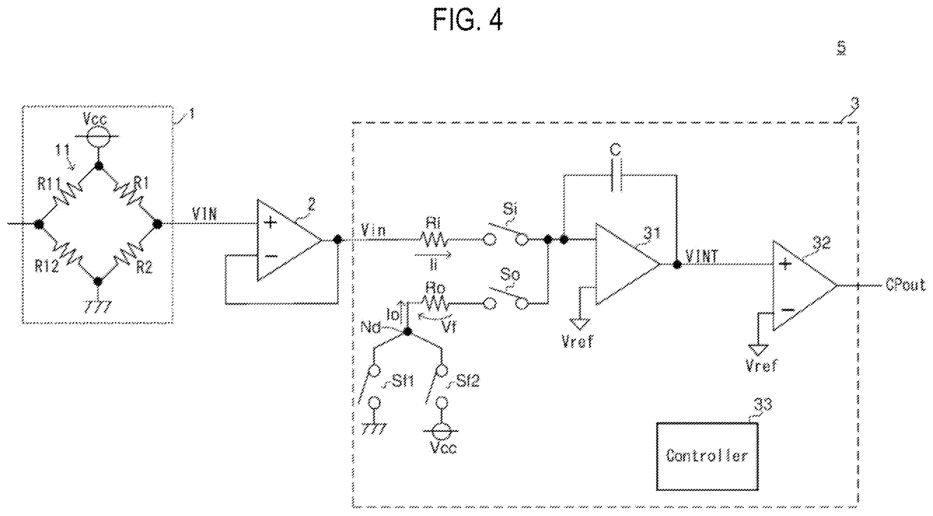

Embodiments of the present disclosure implemented to solve the above-described challenge will be described below. FIG. 4 is a diagram showing a configuration of a sensor device 5 according to a first embodiment of the present disclosure. A difference between the configuration shown in FIG. 4 and the configuration of the above-described comparative example (FIG. 1) is an AD converter 3.

The AD converter 3 shown in FIG. 4 is provided with a discharging switch Sf1 and a charging switch Sf2 as compared with the AD converter 30 (FIG. 1) according to the above-described comparative example. Further, the AD converter 3 shown in FIG. 4 is provided with a controller 33. The controller 33 is configured to control ON/OFF of each of an input switch Si, an output switch So, a discharging switch Sf1, and a charging switch Sf2.

The discharging switch Sf1 is connected between a second end of the output resistor Ro and an application end of a ground potential. The charging switch Sf2 is connected between the second end of the output resistor Ro and an application end of a power supply voltage Vcc.

In other words, the AD converter 3 includes the output resistor Ro connected between a first input end of an amplifier 31 and a node Nd, the discharging switch Sf1 connected between the node Nd and the application end of the ground potential, and the charging switch Sf2 connected between the node Nd and the application end of the power supply voltage Vcc.

In the present embodiment, an offset regulation period is provided, as will be described later, and in order to cancel increase/decrease in a charging amount of a capacitor C due to an offset of an input voltage Vin, the capacitor C is discharged through a path via the discharging switch Sf1, or the capacitor C is charged through a path via the charging switch Sf2.

Next, an AD conversion operation in the present embodiment will be described in detail. Each of the input switch Si, the output switch So, the discharging switch Sf1, and the charging switch Sf2 is controlled by the controller 33.

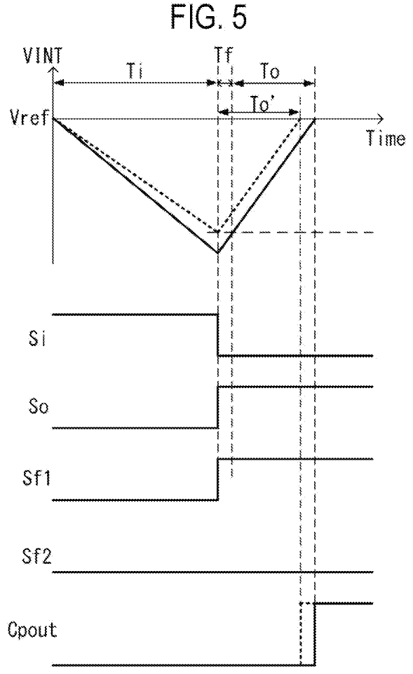

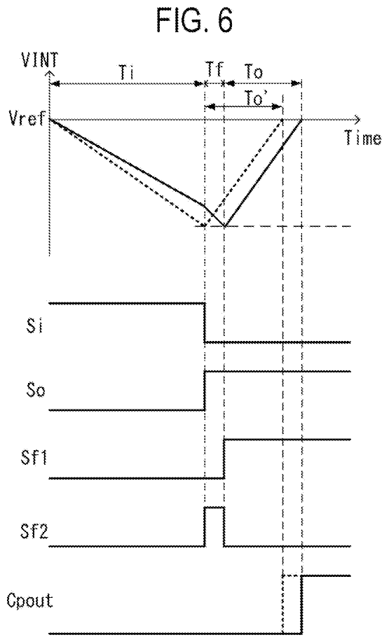

First, a case where the offset of the input voltage Vin is a positive value (ΔV>0) will be described with reference to a timing chart of FIG. 5. FIG. 5 and FIG. 6 to be described later show a waveform of an output voltage VINT, ON/OFF state of the input switch Si, ON/OFF state of the output switch So, ON/OFF state of the discharging switch Sf1, ON/OFF state of the charging switch Sf2, and a waveform of a comparator output CPout, from top to bottom. As for the ON/OFF state, a high level indicates an ON state, and a low level indicates an OFF state.

First, from the OFF state of the input switch Si, the output switch So, the discharging switch Sf1, and the charging switch Sf2, the input switch Si is switched to the ON state, whereby the input current Ii flows through the input resistor Ri, and the capacitor C is charged. Here, in the output voltage VINT of FIG. 5, a solid line indicates a case where the offset occurs, and a broken line indicates a case where the offset does not occur. Due to the charging of the capacitor C, the output voltage VINT drops from the reference voltage Vref with a larger slope than when there is no offset.

The capacitor C is charged during the charging period Ti which is a fixed value, and at a timing when the charging period Ti has elapsed, the input switch Si is switched to the OFF state, the output switch So and the discharging switch Sf1 are switched to the ON state, and the offset regulation period Tf is started. At this time, the output current Io flows from the output resistor Ro toward the ground potential via the discharging switch Sf1, and the capacitor C is discharged. Therefore, as shown in FIG. 5, the output voltage VINT rises toward the reference voltage Vref during the offset regulation period Tf.

After the offset regulation period Tf elapses, the state of each switch is maintained, and the discharging period To is started. At this time, as shown in FIG. 5, the output voltage VINT continues to rise. Then, when the output voltage VINT reaches the reference voltage Vref, the comparator output CPout switches from a low level to a high level, and the discharging period To ends.

In this manner, the offset regulation period Tf is provided after the charging period Ti, the increase in the charging amount of the capacitor C due to the positive offset ΔV is canceled by the discharging during the offset regulation period Tf, and the discharging period To is counted from the end timing of the offset regulation period Tf. As a result, it is possible to suppress an error between the discharging period To′ (its counting starts from the end timing of the charging period Ti) counted when there is no offset and the discharging period To. That is, AD conversion output may be performed with high accuracy even when the positive offset occurs.

Next, a case where the offset of the input voltage Vin is a negative value (ΔV<0) will be described with reference to a timing chart of FIG. 6.

First, from the OFF state of the input switch Si, the output switch So, the discharging switch Sf1, and the charging switch Sf2, the input switch Si is switched to the ON state, whereby the input current Ii flows through the input resistor Ri, and the capacitor C is charged. Here, in the output voltage VINT of FIG. 6, a solid line indicates a case where the offset occurs, and a broken line indicates a case where the offset does not occur. Due to the charging of the capacitor C, the output voltage VINT drops from the reference voltage Vref with a smaller slope than when there is no offset.

The capacitor C is charged during the charging period Ti which is a fixed value, and at a timing when the charging period Ti has elapsed, the input switch Si is switched to the OFF state, the output switch So and the charging switch Sf2 are switched to the ON state, and the offset regulation period Tf is started. At this time, the output current Io flows from the power supply voltage Vcc toward the output resistor Ro via the charging switch Sf2, and the capacitor C is charged. Therefore, as shown in FIG. 6, the output voltage VINT further drops during the offset regulation period Tf.

When the offset regulation period Tf elapses, the discharging switch Sf1 is switched to the ON state, the charging switch Sf2 is switched to the OFF state, and the discharging period To is started. At this time, the capacitor C is discharged by the output current Io, and as shown in FIG. 6, the output voltage VINT rises toward the reference voltage Vref. Then, when the output voltage VINT reaches the reference voltage Vref, the comparator output CPout switches from a low level to a high level, and the discharging period To ends.

In this manner, the offset regulation period Tf is provided after the charging period Ti, the decrease in the charging amount of the capacitor C due to the negative offset ΔV is canceled by the charging during the offset regulation period Tf, and the discharging period To is counted from the end timing of the offset regulation period Tf. As a result, it is possible to suppress an error between the discharging period To′ counted when there is no offset and the discharging period To. That is, AD conversion output may be performed with high accuracy even when the negative offset occurs.

As described above, according to the present embodiment, the accuracy of the AD conversion output may be improved with respect to the offset of the input voltage Vin without adding a resistor such as R3 shown in FIG. 3.

Here, the setting of the offset regulation period Tf will be described. Assuming that Q2 is an amount of change in the charges charged in the capacitor C due to the offset ΔV of the input voltage Vin,

Q2=ΔIi×Ti=(ΔV/Ri)×Ti (7)

Assuming that Qf is the charges due to charging/discharging to cancel Q2,

Q2+Qf=0 (8)

Here, Qf=Io×Tf=(Vf/Ro)×Tf (9)

where, Tf: offset regulation period, Vf: voltage across the output resistor Ro

Substituting the equations (7) and (9) into the equation (8),

Tf=(−ΔV/Vf)×(Ro/Ri)×Ti (10)

Therefore, when ΔV>0, Tf is set so that Vf=−Vref in the equation (10), and when ΔV<0, Tf is set so that Vf=Vcc−Vref in the equation (10).

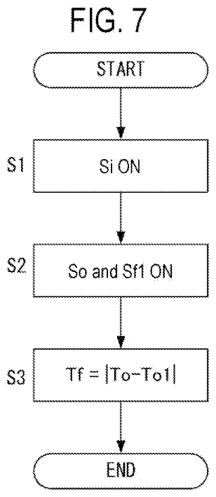

Next, an offset acquisition operation of the input voltage Vin performed before pressure measurement in the sensor device 5 according to the present embodiment will be described with reference to a flowchart of FIG. 7. Each switch is controlled by the controller 33.

When a process shown in FIG. 7 is started, it is assumed that the sensor device 5 is applied with a pressure corresponding to an ideal input voltage Vin in which the discharging period To is a predetermined discharging period To1. Then, in step S1, from the OFF state of the input switch Si, the output switch So, the discharging switch Sf1, and the charging switch Sf2, the input switch Si is switched to the ON state. The capacitor C is charged by setting the input switch Si to the ON state only during the charging period Ti. After that, in step S2, the input switch Si is switched to the OFF state, and the output switch So and the discharging switch Sf1 are switched to the ON state. As a result, the capacitor C is discharged. The controller 33 starts counting the discharging period To at a timing when the charging period Ti ends, and measures the discharging period To until the output voltage VINT reaches the reference voltage Vref and the level of the comparator output CPout switches.

When To>To1, the offset of the input voltage Vin is a positive value, and when To<To1, the offset of the input voltage Vin is a negative value. Therefore, in step S3, the controller 33 acquires an absolute value of To−To1 as the offset regulation period Tf.

The offset regulation period as described above may be acquired before product shipment of the sensor device 5, and the acquired offset regulation period may be stored in a nonvolatile memory (not shown) included in the controller 33. In this case, when the sensor device 5 is used as a product, the offset regulation period may be read from the nonvolatile memory each time the sensor device 5 is activated before pressure measurement, and the offset regulation period may be used during the pressure measurement.

When the sensor device 5 is used as a product, in a case where there is an environment in which a predetermined pressure may be applied to the sensor device 5 each time before pressure measurement, the offset regulation period may be acquired each time. In this case, it is also possible to cope with aging.

The AD converter 3 according to the present embodiment may be configured without the output switch So. However, when various switches such as the input switch Si include MOSFETs (metal-oxide-semiconductor field-effect transistors), an impedance of a switch to which a power supply voltage or a ground potential is applied is small, and an impedance of a switch to which an intermediate potential is applied is large. As a result, when the output switch So is not provided as described above, a combined resistance of the output resistor Ro, the discharging switch Sf1, and the charging switch Sf2 becomes smaller than a combined resistance of the input resistor Ri and the input switch Si, thereby causing a mismatch. Therefore, by providing the output switch So as in the configuration shown in FIG. 4, pairing of the resistance values is improved.

### 3. Second Embodiment

Next, a second embodiment of the present disclosure will be described. In the present embodiment, a configuration of a sensor device 5 is the same as that of the first embodiment (FIG. 4), but a method of AD conversion operation is different from that of the first embodiment.

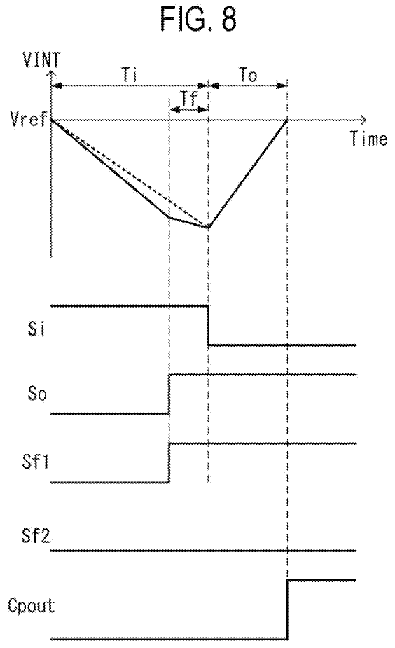

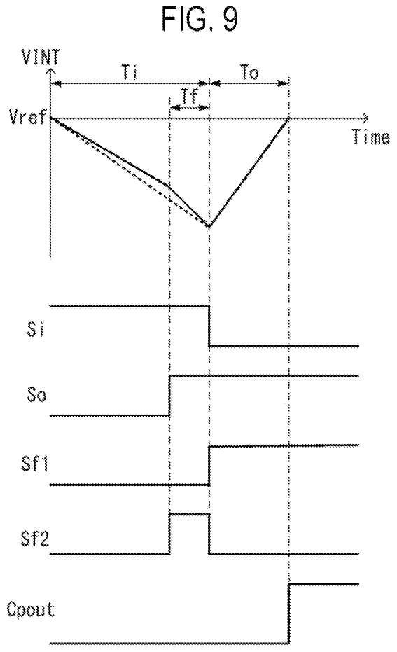

First, a case where the offset of the input voltage Vin is a positive value (ΔV>0) will be described with reference to a timing chart of FIG. 8. Types of waveforms shown in FIG. 8 and FIG. 9 to be described later are the same as those in FIGS. 5 and 6.

First, from the OFF state of the input switch Si, the output switch So, the discharging switch Sf1, and the charging switch Sf2, the input switch Si is switched to the ON state, whereby the input current Ii flows through the input resistor Ri, and the capacitor C is charged. Here, in the output voltage VINT of FIG. 8, a solid line indicates a case where an offset occurs, and a broken line indicates a case where no offset occurs. Due to the charging of the capacitor C, the output voltage VINT drops from the reference voltage Vref with a larger slope than when there is no offset.

At a timing preceding the end timing of the charging period Ti, which is a fixed value, by the offset regulation period Tf, the output switch So and the discharging switch Sf1 are switched to the ON state while the input switch Si is maintained in the ON state, and the offset regulation period Tf is started. As a result, the capacitor C is discharged by the output current Io while being charged by the input current Ii. Therefore, as shown in FIG. 8, in the offset regulation period Tf, the output voltage VINT has a smaller slope than before and further drops.

When the offset regulation period Tf elapses, the input switch Si is switched to the OFF state, and the discharging period To is started. As a result, as shown in FIG. 8, the output voltage VINT rises toward the reference voltage Vref. Then, when the output voltage VINT reaches the reference voltage Vref, the comparator output CPout switches from a low level to a high level, and the discharging period To ends. AD conversion output is performed by counting the discharging period To.

A case where the offset of the input voltage Vin is a negative value (ΔV<0) will be described with reference to a timing chart of FIG. 9.

First, from the OFF state of the input switch Si, the output switch So, the discharging switch Sf1, and the charging switch Sf2, the input switch Si is switched to the ON state, whereby the input current Ii flows through the input resistor Ri, and the capacitor C is charged. Here, in the output voltage VINT of FIG. 9, a solid line indicates a case where an offset occurs, and a broken line indicates a case where no offset occurs. Due to the charging of the capacitor C, the output voltage VINT drops from the reference voltage Vref with a smaller slope than when there is no offset.

At a timing preceding the end timing of the charging period Ti, which is a fixed value, by the offset regulation period Tf, the output switch So and the charging switch Sf2 are switched to the ON state while the input switch Si is maintained in the ON state, and the offset regulation period Tf is started. As a result, the capacitor C is charged by the output current Io while being charged by the input current Ii. Therefore, as shown in FIG. 9, in the offset regulation period Tf, the output voltage VINT has a greater slope than before, and further drops.

When the offset regulation period Tf elapses, the input switch S1 and the charging switch Sf2 are switched to the OFF state, the discharging switch Sf1 is switched to the ON state, and the discharging period To is started. As a result, as shown in FIG. 9, the output voltage VINT rises toward the reference voltage Vref. Then, when the output voltage VINT reaches the reference voltage Vref, the comparator output CPout switches from a low level to a high level, and the discharging period To ends. AD conversion output is performed by counting the discharging period To.

By measuring the discharging period To in this way, accuracy of the AD conversion output is improved even when the positive and negative offsets occur. In particular, in the present embodiment, since the offset regulation period Tf overlaps the charging period Ti, the AD conversion time may be shortened.

### 4. Third Embodiment

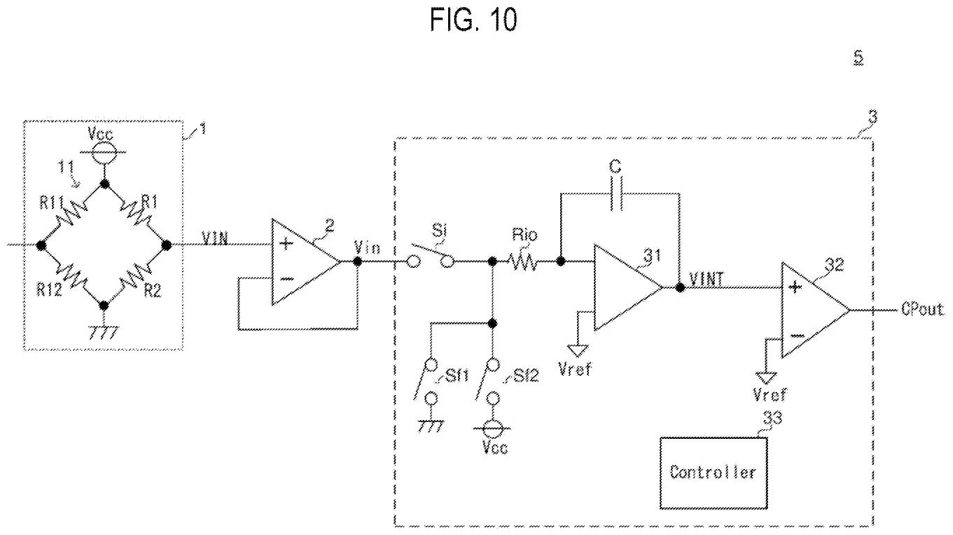

FIG. 10 is a diagram showing a configuration of a sensor device 5 according to a third embodiment of the present disclosure. In the present embodiment, in the AD converter 3, an input resistor and an output resistor are shared by an input/output resistor Rio. The application end of the input voltage Vin is connected to one end of the input switch Si, and one end of the input/output resistor Rio is connected to the other end of the input switch Si. The other end of the input/output resistor Rio is connected to the first input end of the amplifier 31. One end of the input/output resistor Rio is connected to the discharging switch Sf1 and the charging switch Sf2.

In this manner, in a case where the resistance values of the input resistor Ri and the output resistor Ro in the first embodiment are the same, it is also possible to use the common input/output resistor Rio as in the present embodiment.

### 5. Fourth Embodiment

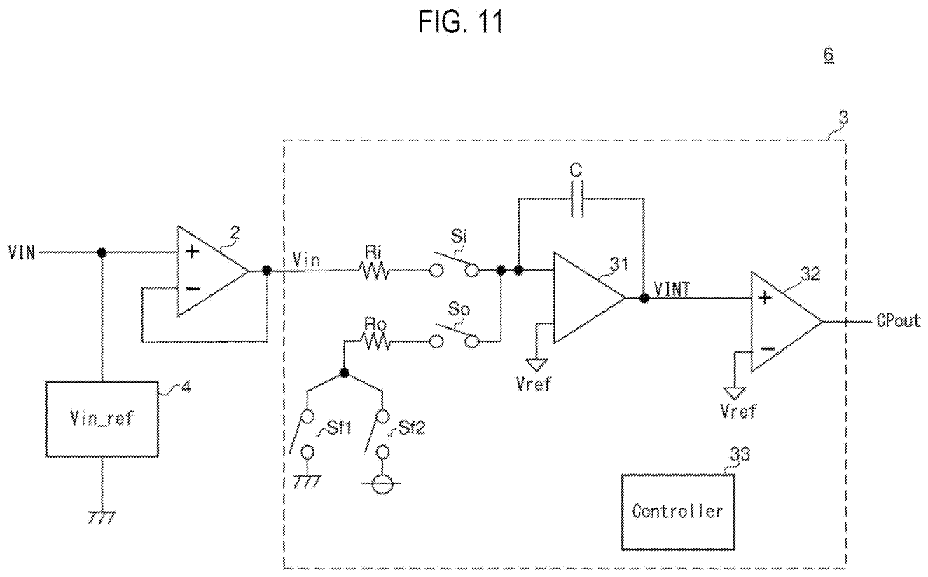

FIG. 11 is a diagram showing a configuration of a voltage measuring device 6 according to a fourth embodiment of the present disclosure. The voltage measuring device 6 does not include a MEMS sensor on the front side, and an input voltage VIN is input to the voltage follower 2. As a result, the input voltage VIN is AD-converted and measured by the AD converter 3.

A reference input voltage generating circuit 4 is included in the voltage measuring device 6. The reference input voltage generating circuit 4 is configured to generate a reference input voltage Vin_ref input to the voltage follower 2.

In the present embodiment, the same offset acquisition operation as in the above-described flowchart shown in FIG. 7 is performed before voltage measurement. When the flowchart shown in FIG. 7 is started, the reference input voltage Vin_ref corresponding to an ideal input voltage Vin, such that the discharging period To becomes a predetermined discharging period To1, is generated by the reference input voltage generating circuit 4. Then, an offset regulation period is acquired as shown in the flowchart of FIG. 7. During voltage measurement, the reference input voltage generating circuit 4 stops generating the reference input voltage Vin_ref.

In this manner, in the embodiment, even in a case where an offset occurs in the input voltage Vin caused by an input stage (for example, the voltage follower 2), accuracy of the AD conversion output may be improved.

### 6. Others

Although exemplary embodiments have been described above, various modifications of the embodiments can be made within the scope of the present disclosure.

### 7. Supplementary Notes

As described above, for example, an AD converter (3) according to one aspect of the present disclosure includes:
an amplifier (31) having a first input end and a second input end connected to an application end of a reference voltage (Vref);
a capacitor (C) connecting the first input end of the amplifier and an output end of the amplifier;
a comparator (32) having a first input end connected to the output end of the amplifier and a second input end connected to the application end of the reference voltage;
a first resistor (Ri) connected between an application end of an input voltage (Vin) and the first input end of the amplifier;
a first switch (Si) connected between the application end of the input voltage and the first input end of the amplifier;
a second resistor (Ro) connected between the first input end of the amplifier and a first node (Nd);
a second switch (Sf1) connected between the first node and an application end of a ground potential; and
a controller (33) configured to perform ON/OFF control of the first switch and the second switch,
wherein the controller is configured to start charging the capacitor by switching the first switch to an ON state, thereafter discharge the capacitor by setting the second switch to an ON state during an offset regulation period (Tf) so as to cancel an increase in the charging amount of the capacitor due to an offset of the input voltage, and measure a discharging period (To) from the end of the offset regulation period to the switching of an output level of the comparator (first configuration, FIG. 4).

Further, in the first configuration, the controller (33) may be configured to maintain the first switch (Si) in the ON state for a predetermined charging period (Ti) and switch the first switch to an OFF state and the second switch (Sf1) to an ON state when the charging period ends, and the offset regulation period (TO is started when the charging period ends (second configuration, FIG. 5).

Further, in the first configuration, the controller (33) may be configured to maintain the first switch (Si) in the ON state for a predetermined charging period (Ti) and switch the second switch (Sf1) to an ON state before the offset regulation period (TO from the end of the charging period (third configuration, FIG. 8).

Further, in any one of the first to third configurations, a third switch (Sf2) connected between the first node (Nd) and the application end of a power supply voltage (Vcc) may be further included,

wherein the controller (33) is configured to start charging the capacitor by switching the first switch (Si) to an ON state, thereafter discharge the capacitor by setting the third switch (Sf2) to an ON state during the offset regulation period so as to cancel a decrease in the charging amount of the capacitor due to the offset of the input voltage (Vin), and measure the discharging period from the end of the offset regulation period to the switching of the output level of the comparator (fourth configuration, FIG. 4).

Further, in the fourth configuration, the controller (33) may be configured to maintain the first switch (Si) in the ON state for a predetermined charging period (Ti), switch the first switch to an OFF state and the third switch (Sf2) to an ON state when the charging period ends, and switch the third switch to an OFF state and the second switch (Sf1) to an ON state when the offset regulation period (TO ends (fifth configuration, FIG. 6).

Further, in the fourth configuration, the controller (33) may be configured to maintain the first switch (Si) in the ON state for a predetermined charging period (Ti), switch the third switch (Sf2) to an ON state before the offset regulation period (TO from the end of the charging period, and switch the third switch (Sf2) to an OFF state and the second switch (Sf1) to an ON state when the offset regulation period ends (sixth configuration, FIG. 9).

Further, in any one of the first to sixth configurations, the first resistor (Ri) and the second resistor (Ro) may be configured with separate resistors (seventh configuration, FIG. 4). Further, in the seventh configuration, a fourth switch (So) may be further included,
wherein the first, second, third, and fourth switches are composed of MOSFETs,
wherein the first switch (Si) is connected between the first resistor (Ri) and the first input end of the amplifier (31), and
wherein the fourth switch is connected between the second resistor (Ro) and the first input end of the amplifier (eighth configuration, FIG. 4).

Further, in any one of the first to sixth configurations, the first resistor and the second resistor may be the same resistor (Rio) (ninth configuration, FIG. 10).

Further, in any one of the first to ninth configurations, in a state where the input voltage (Vin), which is ideally a predetermined value, is applied, the controller (33) may be configured to maintain the first switch (Si) in the ON state only for a predetermined charging period (Ti), switch the first switch to the OFF state and the second switch (Sf1) to the ON state when the charging period ends, measure the discharging period (To) from the end of the charging period to the switching of the output level of the comparator (32), and acquire the absolute value of a difference between the measured discharging period and the ideal discharging period (To1) as the offset regulation period (TO (tenth configuration, FIG. 7).

Further, in the tenth configuration, when a device (5) including the AD converter (3) is activated, the controller (33) may be configured to perform an acquisition operation of the offset regulation period before starting the measurement operation using the AD converter (eleventh configuration).

Further, in the tenth configuration, a nonvolatile memory configured to store the acquired offset regulation period may be further included (twelfth configuration).

Further, a sensor device (5) according to an aspect of the present disclosure includes:
an AD converter (3) of any one of the tenth to twelfth configurations; and
a sensor part (1) provided in the preceding stage of the AD converter,
wherein under the environment corresponding to the input voltage of the predetermined value, the controller (33) is configured to perform the acquisition operation of the offset regulation period (thirteenth configuration, FIG. 4).

Further, a voltage measuring device (6) according to an aspect of the present disclosure includes:
an AD converter (3) of any one of the tenth to twelfth configurations; and
a voltage generating circuit (4) provided in the preceding stage of the AD converter,
wherein the voltage generating circuit is configured to generate a voltage having a voltage value corresponding to the input voltage of the predetermined value when the controller (33) performs the acquisition operation of the offset regulation period (fourteenth configuration, FIG. 11).

Further, a sensor device (5) according to an aspect of the present disclosure includes:
an AD converter (3) of any one of the first to twelfth configurations; and
a resistance bridge circuit (11) provided in the preceding stage of the AD converter (fifteenth configuration, FIG. 4).

### INDUSTRIAL APPLICABILITY

The present disclosure may be used, for example, for various sensor devices.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An AD converter comprising:
an amplifier including a first input end and a second input end connected to an application end of a reference voltage;
a capacitor configured to connect the first input end of the amplifier and an output end of the amplifier;
a comparator including a first input end connected to the output end of the amplifier and a second input end connected to the application end of the reference voltage;
a first resistor connected between an application end of an input voltage and the first input end of the amplifier;
a first switch connected between the application end of the input voltage and the first input end of the amplifier;
a second resistor connected between the first input end of the amplifier and a first node;
a second switch connected between the first node and an application end of a ground potential; and
a controller configured to perform ON/OFF control of the first switch and the second switch,
wherein the controller is further configured to start charging the capacitor by switching the first switch to an ON state, thereafter discharge the capacitor by setting the second switch to an ON state during an offset regulation period so as to cancel an increase in a charging amount of the capacitor due to an offset of the input voltage, and measure a discharging period from an end of the offset regulation period to switching of an output level of the comparator.

2. The AD converter of claim 1, wherein the controller is further configured to maintain the first switch in the ON state for a predetermined charging period and switch the first switch to an OFF state and the second switch to the ON state when the charging period ends, and wherein the offset regulation period is started when the charging period ends.

3. The AD converter of claim 1, wherein the controller is further configured to maintain the first switch in the ON state for a predetermined charging period, and switch the second switch to the ON state before the offset regulation period from an end of the charging period.

4. The AD converter of claim 1, further comprising a third switch connected between the first node and an application end of a power supply voltage,
wherein the controller is further configured to start charging the capacitor by switching the first switch to the ON state, thereafter charge the capacitor by setting the third switch to an ON state during the offset regulation period so as to cancel a decrease in the charging amount of the capacitor due to the offset of the input voltage, and measure the discharging period from the end of the offset regulation period to the switching of the output level of the comparator.

5. The AD converter of claim 4, wherein the controller is further configured to maintain the first switch in the ON state for a predetermined charging period, switch the first switch to an OFF state and the third switch to the ON state when the charging period ends, and switch the third switch to an OFF state and the second switch to the ON state when the offset regulation period ends.

6. The AD converter of claim 4, wherein the controller is further configured to maintain the first switch in the ON state for a predetermined charging period, switch the third switch to the ON state before the offset regulation period from the end of the charging period, and switch the third switch to an OFF state and the second switch to the ON state when the offset regulation period ends.

7. The AD converter of claim 1, wherein the first resistor and the second resistor are separate resistors.

8. The AD converter of claim 7, further comprising a third switch and a fourth switch,
wherein the first switch, the second switch, the third switch, and the fourth switch are configured by MOSFETs,
wherein the first switch is connected between the first resistor and the first input end of the amplifier,
wherein the third switch is connected between the first node and an application end of a power supply voltage and
wherein the fourth switch is connected between the second resistor and the first input end of the amplifier.

9. The AD converter of claim 1, wherein the first resistor and the second resistor are the same resistor.

10. The AD converter of claim 1, wherein in a state where the input voltage, which is ideally a predetermined value, is applied, the controller is further configured to maintain the first switch in the ON state only for a predetermined charging period, switch the first switch to an OFF state and the second switch to the ON state when the charging period ends, measure the discharging period from the end of the charging period to the switching of the output level of the comparator, and acquire an absolute value of a difference between the measured discharging period and an ideal discharging period as the offset regulation period.

11. The AD converter of claim 10, wherein when a device including the AD converter is activated, the controller is further configured to perform an acquisition operation of the offset regulation period before starting a measurement operation in which the AD converter is used.

12. The AD converter of claim 10, further comprising a nonvolatile memory configured to store the acquired offset regulation period.

13. A sensor device comprising:
the AD converter of claim 10; and
a sensor installed in a preceding stage of the AD converter,
wherein under an environment corresponding to the input voltage of the predetermined value, the controller is further configured to perform an acquisition operation of the offset regulation period.

14. A voltage measuring device comprising:
the AD converter of claim 10; and
a voltage generating circuit installed in a preceding stage of the AD converter,
wherein the voltage generating circuit is configured to generate a voltage of a voltage value corresponding to the input voltage of the predetermined value when the controller performs an acquisition operation of the offset regulation period.

15. A sensor device comprising:
the AD converter of claim 1; and
a resistance bridge circuit installed in a preceding stage of the AD converter.
